(19) United States
(12) Patent Application Publication
(10) Pub. No.: US 2025/0307500 A1
(43) Pub. Date: Oct. 2, 2025

(54) METHODOLOGY FOR MACHINE LEARNING DRIVEN HISTORY-MATCH QUALITY ASSESSMENT

(71) Applicant: Saudi Arabian Oil Company, Dhahran (SA)

(72) Inventors: Babatope Kayode, Dhahran (SA); Tareq M. Al-Zahrani, Dammam (SA)

(21) Appl. No.: 19/088,402

(22) Filed: Mar. 24, 2025

Related U.S. Application Data
(60) Provisional application No. 63/571,097, filed on Mar. 28, 2024.

(51) Int. Cl. G06F 30/27; G06F 30/28

(52) U.S. Cl. CPC G06F 30/27; G06F 30/28

(57) ABSTRACT

Methods, systems, and computer-readable storage media for machine learning driven history-match quality assessment. Probe data collected by probes included in operating wells or observation wells within a field is received. A list of training dataset including examples of Good and Acceptable matches is received. Data density distribution a matching the probe data to simulated data for respective parameters is learned. Training parameters for subsequent history-match assessment from the labeled input for the respective parameters can be retrieved. A well history-match quality is determined within the field using the parameter match assessment to provide well planning within the field.

### RELATED APPLICATIONS

This application claims the benefit of priority to U.S. Patent Application 63/571,097, filed on Mar. 28, 2024, the contents of which are incorporated by reference herein.

### TECHNICAL FIELD

This disclosure relates to geological history matching and, more specifically, to machine learning driven history-match quality assessment.

### BACKGROUND

Geological history matching is the process of updating a geological model until its simulated outputs like pressure, water-cut and modular dynamic tester (MDT) matches with historical measured data. Geological history matching relies on computing a set of deviation values, each of which is defined to be a calculated simulator result minus the corresponding surveillance measurement value. The deviation values can include surveillance data, such as rates, water cuts, or gas-oil ratios. The deviation values can be grouped by well, by area, or combining all measurements in a database. Traditional geological history matching is based on simple graphical comparisons of each group of deviation values to show how well the simulation results match the surveillance data. Plot based comparisons can include results from multiple simulations executed using different geological parameters.

### SUMMARY

Implementations of the present disclosure are directed to geological history matching. More particularly, implementations of the present disclosure are directed to machine learning driven history-match quality assessment.

In some implementations, a method includes: receiving, by one or more processors from probes, wherein the probe data is collected by probes included in operating wells or observation wells within a field, and wherein the probe data includes parameters characterizing a surface field conditions and subterranean field conditions indicative of a health of a reservoir within the field; receiving, by the one or more processors, as input a list of training dataset including of examples of simulated data versus the probe data labelled as Good matches and Acceptable matches; learning, by the one or more processors, a data density distribution including a matching between the probe data and simulated data for respective parameters; retrieving, by the one or more processors, training parameters for subsequent history-match assessment from the labeled input for the respective parameters; determining, by the one or more processors, a well history-match quality within the field using the parameter match assessment; providing, by the one or more processors, well planning within the field based on the well history-match quality map, the well planning including a plurality of operations affecting the drilling of sidetrack or infill wells within the field; and triggering, by the one or more processors, execution of one of the plurality of operations.

The foregoing and other implementations can optionally include one or more of the following features, alone or in combination. In particular, implementations can include all the following features:

In an aspect, combinable with any of the previous aspects, the computer-implemented method of the preceding example, includes: displaying an interactive spreadsheet on a display of a user device, wherein the interactive spreadsheet includes parameter matches; receiving an input differentiating between Acceptable data, Good, and Poor data; in response to receiving the input: training a machine learning model on recorded to simulated parameter matches to predict Acceptable data and Good data; generating a respective predicted value for a parameter distribution; and displaying the respective predicted value on the user device. In another aspect, combinable with any of the previous aspects training the machine learning model occurs on the user device. In another aspect, combinable with any of the previous aspects the probe data includes pressures, water-cut and modular dynamic test data. In another aspect, combinable with any of the previous aspects determining, by the one or more processors, the well quality within the field is performed without receiving any additional user inputs. In another aspect, combinable with any of the previous aspects matching, by the one or more processors, the data density distribution to the training data includes determining a fraction of matching data-points. In another aspect, combinable with any of the previous aspects matching, by the one or more processors, the probe data includes determining a data density distribution.

Other implementations of the aspect include corresponding systems, apparatus, and computer programs, configured to perform the actions of the methods, encoded on computer storage devices.

The present disclosure also provides a computer-readable storage medium coupled to one or more processors and having instructions stored thereon which, when executed by the one or more processors, cause the one or more processors to perform operations in accordance with implementations of the methods provided herein.

The present disclosure further provides a system for implementing the methods provided herein. The system includes one or more processors, and a computer-readable storage medium coupled to the one or more processors having instructions stored thereon which, when executed by the one or more processors, cause the one or more processors to perform operations in accordance with implementations of the methods provided herein.

It is appreciated that methods in accordance with the present disclosure can include any combination of the aspects and features described herein. That is, methods in accordance with the present disclosure are not limited to the combinations of aspects and features specifically described herein, but also include any combination of the aspects and features provided.

Implementations described in the present disclosure, provide multiple technical advantages. For example, the machine learning driven history-match quality assessment described in the present disclosure is based on geological models that integrate multiple parameters characterizing surface and subterranean reservoir characteristics, rather than disjointly treating limited sets of data, which can lead to significant errors in characterization of reservoirs and wells. Another advantage of the described technology is that it provides key recommended actions for improving field (well and reservoir) safety and security to ensure continuation of well operations. Furthermore, the described reservoir characteristic assessment approach allows a continuous training of machine learning models that are integrated in geomechanical models. Fine tuning of machine learning models can maximize the safety breach prevention. Moreover, collaboratively training the machine learning models can promote optimal threat prevention performance in view of evolving conditions leading to potential safety breaches. Another advantage of the described technology is that the described reservoir characteristic assessment allows users (e.g., geomechanical managers) to optimize geomechanical model settings or to optimize other aspects of machine and device operations for continuation of operation of wells and optimization of reservoir management.

The details of one or more implementations of the subject matter of the specification are set forth in the accompanying drawings and the description below. Other features, aspects, and advantages of the subject matter can become apparent from the description, the drawings, and the claims.

### DESCRIPTION OF DRAWINGS

The accompanying drawings, which are incorporated in and constitute a part of this specification, show particular aspects of the subject matter disclosed herein and, together with the description, help explain some of the principles associated with the disclosed implementations. In the drawings,

FIG. 1 is a block diagram of an example system that can be used to execute implementations of the present disclosure;

FIG. 2 illustrates an example workflow that can be used to execute implementations of the present disclosure;

FIG. 3A illustrates an example realization evaluation report generated by the example system that can be used to execute implementations of the present disclosure;

FIG. 3B depicts an example multi-parameter comparison report generated by the example system that can be used to execute implementations of the present disclosure;

FIG. 4 illustrates an example process that can be used to execute implementations of the present disclosure;

FIG. 5 depicts a block diagram illustrating a computing system, in accordance with some example implementations; and

FIG. 6 illustrates hydrocarbon production operations, in accordance with some example implementations.

When practical, like labels are used to refer to same or similar items in the drawings.

### DETAILED DESCRIPTION

Implementations of the present disclosure are directed to geological history matching. More particularly, implementations of the present disclosure are directed to machine learning driven history-match quality assessment. History-match (HM) quality assessment is performed to calibrate the performance (pressure, water-cut, pressure) of well three-dimensional simulation models to the equivalent physical measurements of respective wells. The physical measurements of respective wells can be collected by probes. The probes can collect probe data including actual reservoir performance, such as well rates (production and injection), water cuts, gas-oil ratios (GOR), static bottomhole pressures (BHP), and possibly zone pressures. The probe data can be provided as input to automatically update geological history matching. The geological history matching can be optimized using training data of reservoir performance characterization. The matching results can be converted into a quantitative value representing a degree to which the simulated and measured parameters are similar on well-by-well basis. A well quality can be estimated within the field using the pressure match assessment and the water cut assessment. The well quality can be used for generating a map of the history-matching quality of the wells, and by making a map of the history-matching quality, it is easier to detect areas/regions of the simulation model where reservoir characterization is robust. Robust simulation model implies that majority of the wells in the model (or region of the model) have Good or Acceptable history-matching quality. It is believed that prediction results are more reliable and less uncertain in such models. The history-matching map can be used for guiding well planning within the field, by selecting operations affecting oil extraction from the field. In the history-matching map areas having Good or Acceptable history-matching quality, more wells can be drilled. The wells in the area that are producing a lot of water can be sidetracked to increase oil production, the organization finances and securities and exchange valuations. The identified plans and operations can be automatically triggered.

Traditionally, two approaches have been used in deciding whether a HM quality is Good, Acceptable, or Poor. The two common approaches are visualization and root mean squared error (RMSE). Visualization is subjective, influenced by the user's experience, while RMSE can be deceptive in the presence of data outliers or anomalies. Visualization includes visual inspection of the plot of simulation results and historical data to decide whether the two are matching. The challenge is that the process is based on a subjective definition of a satisfactory match. Even same user may be subjective about what is satisfactory or not depending on mood, fatigue, and other factors. A key challenge with the visualization approach is that it is time consuming when the project involves several hundreds of wells which would require to be evaluated for various historical objectives like historical pressure, vertically distributed formation pressure, and water-cut. Another particular challenge with the visualization approach is during assisted history matching wherein several (e.g., sometimes hundreds to thousands) of simulation runs are submitted to cover parameter uncertainty space in the hope one or more would have a satisfactory history match of all the wells in the model. The large data volume makes the visualization approach practically impossible to evaluate by traditionally analyzing several hundred wells within a simulation run. To cope with such difficulty is why the use of an error weighted parameter called root mean squared error was developed. Another challenge with the visualization approach is lack of applicability to history matching automation, where it is expected that the numerical simulator makes the decision by itself on the quality of the simulation cases.

In the RMSE approach, errors between the observed data and the simulation response is computed. The sum of the squared errors calculated and eventually, the square-root of the sum of the squared error is computed in order to obtain a single real number indicative of the history match quality. The challenge with the RMSE approach is that the resulting number output is meaningless to the user without a visualization. If the RMSE=0, the user knows that is a perfect match, but it is rarely ever the case. A non-zero RMSE of 215.6 for example means nothing to the user in terms of history match quality without a visualization. Another challenge with the application of RMSE is that it can be misled by the presence of data outlier, thereby leading to a different judgement than an engineer can make through the visualization approach. The RMSE is particularly used in the scenario of assisted history matching using automatic techniques where the program is able to determine the best model scenarios during a batch of simulation runs through the calculated RMSE.

Addressing the challenges of traditional geological history matching that lack objective characterization of reservoir performance, the machine learning driven history-match quality assessment described in the present disclosure enable accurate and objective representation of characterization of reservoir performance. The machine learning models are trained using Good and Acceptable matches for measured to simulated reservoir deviation distribution plots. The machine learning models can be tailored to integrate the human mind model (HMM) by learning a fraction of total data that was previously labeled as corresponding to an Acceptable or a Good category.

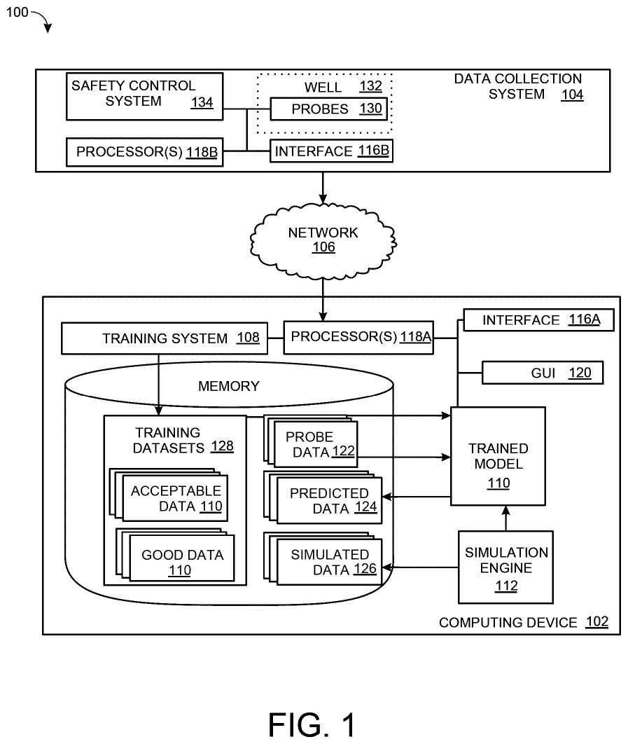

An advantage of the implementations described in the present disclosure is that the machine learning driven history-match quality assessment models integrate multi-parameter comparisons for objective reservoir characterization. Configurations of the machine learning driven history-match quality assessment models can be adjusted and retrained to reflect particular field characteristics relative to reservoir planning goals and relative to hydrocarbon reservoir compliance requirements that are associated to highest safety standards. Another advantage of the described technology is that it provides key recommended actions for improving field (well and hydrocarbon reservoir) safety to ensure optimization of oil extraction from the field and optimization of well operations. Furthermore, the described hydrocarbon reservoir assessment approach allows a continuous training of machine learning models that are integrated in geomechanical models. Fine tuning of machine learning models can maximize the accuracy of hydrocarbon reservoir characterization. Moreover, collaboratively training the machine learning models can promote optimal accident prevention performance in view of evolving conditions leading to potential safety breaches. Other advantages of the machine learning driven history-match quality assessment techniques are described with reference to FIGS. 1-6.

FIG. 1 is a block diagram illustrating an example system 100 for machine learning driven history-match quality assessment within fields including one or more wells and one or more hydrocarbon reservoirs). Specifically, the illustrated example system 100 includes or is communicably coupled with a computing device 102, a data collection system 104, a network 106. Although shown separately, in some implementations, functionality of two or more systems or components of the example system 100 can be provided by multiple computing devices, a computing device connected to a computing system or a server. In some implementations, the functionality of one illustrated system, computing device, or component can be provided by multiple systems, servers, or components, respectively.

In general, the computing device 102 manages machine learning driven history-match quality assessment. The computing device 102 can be any computing device operable to connect to or communicate in the network(s) 106 using a wireline or wireless connection. For example, the computing device 102 includes an electronic computer device operable to receive, transmit, process, and store any appropriate data associated with the example system 100 of FIG. 1. The computing device 102 is generally intended to encompass any client computing device such as a laptop/notebook computer, wireless data port, smart phone, personal data assistant (PDA), tablet computing device, one or more processors within these devices, or any other suitable processing device. The computing device 102 includes a training system 108, a trained model 110 (e.g., an HMM model), a simulation engine 112, a memory 114, an interface 116A, a processor 118A, and a graphical user interface (GUI) 120.

The memory 114 can include any type of memory or database module and can take the form of volatile and/or non-volatile memory including, without limitation, magnetic media, optical media, random access memory (RAM), read-only memory (ROM), removable media, or any other suitable local or remote memory component. The memory 114 can store various objects or data, including caches, classes, frameworks, applications, backup data, business objects, jobs, web pages, web page templates, database tables, database queries, repositories storing safety data and/or dynamic information, and any other appropriate information including any parameters, variables, algorithms, instructions, rules, constraints, or references thereto associated with the purposes of the computing device 102 and the data collection system 104, respectively. For example, the memory 114 can store raw data (e.g., data received from the data collection system 104) and processed data (e.g., inputs and outputs of the training system 108, the trained model 110, and the simulation engine 112). The raw data can include probe data 122. The probe data 122 can include live monitoring data, such as well rates (production rates and injection rates), water cuts, gas-oil ratios (GOR), static bottomhole pressures (BHP), and one or more zone pressures. The processed data can include predicted data 124, simulated data 126, and training datasets 128. The predicted data 124 can be generated by the trained model 110 including a machine learning model to analyze wells and hydrocarbon reservoirs within a field and to monitor reservoir characterization. The simulated data 126 can be generated by the simulation engine 112 configured to predict reservoir parameters over time. The training datasets 128 can be generated by the training system 108 configured to classify data set types and categorize them.

The GUI 120 can include an input device, such as a keypad, touch screen, or other device that can accept user information, and an output device that conveys information associated with the operation of the computing device 102, or the client device itself, including machine learning driven history-match quality assessment data (reports), and/or well operations, respectively. The GUI 120 provides an interface with at least a portion of the example system 100 for any suitable purpose, including generating a visual representation of the data collected by the data collection system 104, data generated by the computing device 102, or data stored by the computing device 102, such as the probe data 122, the predicted data 124, and the simulated data 126, respectively. In particular, the GUI 120 can be used to view and adjust various well planning operations. Generally, the GUI 120 can provide the user with an efficient and user-friendly presentation of machine learning driven history-match quality assessment provided by or communicated within the example system 100. The GUI 120 can include multiple customizable frames or views having interactive fields, pull-down lists, and buttons operated by the user. The GUI 120 can be any suitable graphical user interface, such as a combination of a generic web browser, intelligent engine, and command line interface (CLI) that processes information and efficiently presents the results to the user visually.

The data collection system 104 includes an interface 116B, one or more processors 118B, multiple probes 130 that can be included in one or more wells 132 and an operation control system 134. The operation control system 134 can include a pump control (e.g., to activate or deactivate pumps to manage fluid levels through conduits, such as pipelines, and prevent overproduction or underproduction), injection systems (e.g., to automatically inject chemicals to manage scale, corrosion, or hydrate formation based on real-time well conditions), a valve operation (e.g., to open or close valves to control the flow of fluids, ensuring balanced pressure and preventing blowouts), well shut-in systems (e.g., to automatically shut in a well if critical parameters exceed safe operating limits, ensuring safety and preventing damage), and/or reservoir management systems (e.g., to adjust injection rates in waterflood or gas injection operations to optimize reservoir pressure and enhance recovery).

Each processor 118A, 118B included in different components of the example system 100 can include a central processing unit (CPU), an application specific integrated circuit (ASIC), a field-programmable gate array (FPGA), or another suitable component. Generally, each processor 118A, 118B executes instructions and manipulates data to perform machine learning driven history-match quality assessment within fields. For example, each processor 118A, 118B executes a functionality required to monitor gas storage in real time within fields, to plan well configurations, to execute well operations and to maintain safety of field operations.

Interfaces 116A, 116B can be used by different components of the example system 100 for communicating with other component systems in a distributed environment—including within the example system 100—connected to the network 106. Generally, the interfaces 116A, 116B each include logic encoded in software and/or hardware in a suitable combination and operable to communicate with the network 106. More specifically, the interfaces 116A, 116B can include software supporting one or more communication protocols associated with communications such that the network 106 or interface's hardware is operable to communicate physical signals within and outside of the illustrated system 100.

The safety control system 128 controls operation of the probes 130 and directs collected data to the computing device 102 for storage, for further analysis, and for matching. The probes 130 can collect surface data and subterranean data within a field including one or more wells and one or more hydrocarbon reservoirs. The probes 130 can be coupled to or integrated in different types of components of the wells, to continuously monitor gas storage and secure the safety of the field operations.

The probes 130 can include thermal, acoustic, and pressure sensors that be used to measure geomechanical data including surface data and petrophysical properties of subterranean formations. The surface data can include pressure data and flow data measured by probes 130 distributed across a surface of an analyzed region including one or more hydrocarbon reservoirs, a wellhead, a machine, and/or an industrial apparatus. The subterranean data can include information such as seismic data, pressure data, flow data, and/or image logs that can be used to build a natural fracture network. Image logs can represent fractures observed in a wellbore. The probes 130 can be static or mobile sensors recording data at a fixed location or multiple locations within the field. The probes 130 can record data according to a set frequency and/or a schedule and can transmit the collected data in real time (within less than a second after data collection) to the computing device 102 to be processed by the trained model 110. The probes 130 can be wired or wirelessly connected to the network 106 to transmit the collected data to the computing device 102.

The probes 130, collecting surface data, can be located above a subterranean formation, at a ground surface. The probes 130 can be coupled to (e.g., integrated in) monitored systems or can be separate measurement devices or imaging tools located at particular points of interest within the surface that can correspond to one or more different areas within a geographical region of the field. The probes 130 collecting subterranean data, can be located within a subterranean formation, below the ground surface. For example, one or more probes 130 can be installed near the wellbore to detect subterranean data (e.g., seismic data and/or pressure data) in the proximity of the wellbore. The probes 130 can be attached to a downhole tool that can be lowered into the wellbore to perform subterranean data measurements (e.g., fluid and/or formation measurements). In some examples, the probes 130 can be a single device that is transportable to measure geomechanical data for each formation of the subterranean region. The probe 130 can be located proximal to the hydrocarbon reservoir. A subterranean formation including a hydrocarbon reservoir can have a natural fracture network, where fracturing can most likely occur. The formation data measured by the probes 130 can be used to determine the natural fracturing network. The formation data measured by the probes 130 within the subterranean formations can have different petrophysical properties that can change overtime. By determining the extent of the reservoir characteristics through mapping a complete picture of the subterranean formations within a local area, a basic understanding of which locations can be drilled to achieve a highest hydrocarbon recovery rate can be determined. In some examples, preexisting wells in the drilling or production phases can be used to provide additional data for optimizing placement of additional wells for the respective reservoir already producing hydrocarbons. For example, a drilling environment can include a drilling rig in the drilling phase. During the drilling phase, sensors 130 located at the surface or downhole within the subterranean region, such as sensors attached to a tool on a drill string or sensors attached to a wireline tool, can be used to determine the actual petrophysical properties of the reservoir. Additionally, reservoir properties can be determined in the production phase. By measuring the actual properties of a reservoir, the trained model 110 can include the well location and geometry of the existing well in the drilling environment within the optimization calculations.

In some implementations, the network 106 can include a large computer network, such as a local area network, a wide area network, the Internet, a cellular network, a telephone network, or an appropriate combination thereof connecting any number of communication devices, mobile computing devices, fixed computing devices and server systems. Data exchanged over the network 106, is transferred using any number of network layer protocols, such as internet protocol, multiprotocol label switching, asynchronous transfer mode, Frame Relay, etc. Furthermore, in implementations where the network 106 represents a combination of multiple sub-networks, different network layer protocols are used at each of the underlying sub-networks. In some implementations, the network 106 represents one or more interconnected internetworks, such as the public Internet.

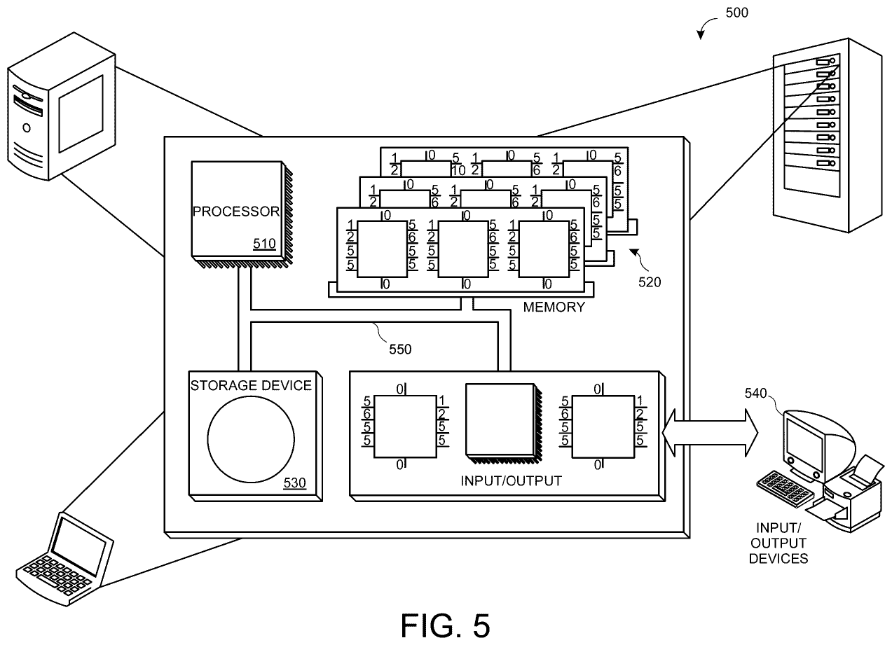

The example system 100 can include any number of computing devices 102 and data collection systems 106 associated with, or external to, the example system 100. Additionally, there can also be one or more additional client devices external to the illustrated portion of system 100 that are capable of interacting with the example system 100 via the network(s) 106. Further, the term “client,” “client device,” and “user” can be used interchangeably as appropriate without departing from the scope of the disclosure. Moreover, while client device can be described in terms of being used by a single user, the disclosure contemplates that many users can use one computer, or that one user can use multiple computers. As used in the present disclosure, the term “computer” is intended to encompass any suitable processing device. For example, although FIG. 1 illustrates a single computing device 102, and a single data collection system 104, the example system 100 can be implemented using a single, stand-alone computing device, two or more server systems, or multiple client devices. According to one implementation, the computing device 102 can also include or be communicably coupled with an e-mail server, a Web server, a caching server, a streaming data server, and/or another suitable server, as described with reference to FIG. 5.

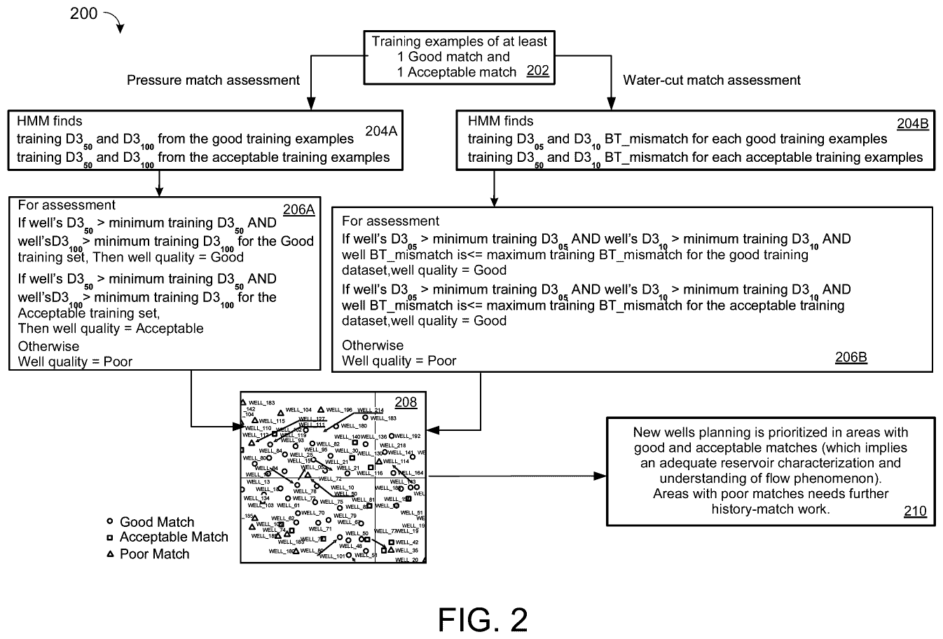

FIG. 2 illustrates an example workflow 200 that can be used to execute implementations of the present disclosure. The example workflow 200 can be performed by any components of the example system 100 (illustrated in FIG. 1), such as the trained model 110 including an HMM model. Operations of the example workflow 200 are described below for illustration purposes only. Operations of the example workflow 200 can be performed by any appropriate device or system, e.g., any appropriate data processing apparatus. Operations of the example workflow 200 can also be implemented as instructions stored on a computer readable medium which can be non-transitory. One or more portions of the example workflow can be displayed by the GUI 120, described with reference to FIG. 1. The example workflow 200 can include an HMM workflow configured to study the data density distribution (D3) using training datasets as guides. The example workflow 200 can be applied to one or more parameter assessment, such as pressure match assessment, water cut match assessment, and modular dynamic test match assessment. In the example workflow 200, illustrated in FIG. 2, training examples for the pressure match assessment and the water cut match assessment are determined.

At 202, training examples of at least one Good match and one Acceptable match are retrieved from a database. In some implementations, parameter matching level can be divided in three categories of history match qualities, such as Good, Acceptable, and Poor. The HMM learns the fraction of total data identified as Good from previously labeled example(s) of a history-match result that was previously labeled as Good. In the particular case of matching water-cut, the HMM considers both the match of the water-breakthrough (BT) as well as the post BT data match. The HMM model processes the training datasets and studies the data density distribution (D3).

The HMM learns the fraction of total data by searching for adequately matched data based on labeled data with known history match result(s) that was identified as having Good quality. In assessing water-cut match, the HMM considers both the match of the water-breakthrough as well as the post breakthrough data match. In a particular implementation, there are three (3) categories of history match qualities namely: Good, Acceptable, and Poor. The labeled data of matches that are considered to be Good and the labeled data considered to be Acceptable are mostly within 50 psi and 100 psi, respectively of the observed data.

For example, a Good history matched well corresponds to a particular fraction of total data points in the well's historical data were matched to within the 50 psi range. The quantity of ‘particular fraction’ is what the HMM model learns from the training dataset provided by the labeled data. A training dataset is a well-match already assessed and labeled. An Acceptable history matched well is one in which a particular fraction of total data-points in the well's historical data were matched to within the 100 psi range. This quantity ‘particular fraction’ is learned by the HMM from the training dataset provided by as labeled data. The quantities of particular fractions learned from the Good and Acceptable training dataset are known as the dataset's data density distribution also termed D3. Training dataset is not required for Poor history match, if any match does not belong to either Good or Acceptable, it is automatically classified as Poor. A separate training dataset is provided for pressure match and water-cut match assessments.

For pressure match training and assessment, the HMM processes the provided training datasets and learns the D3. The HMM determines for each training data, what fraction of the total pressure points were matched to within 50 psi, being referred to as D3₅₀. The HMM determines, what fraction of the total pressure points are matched within 100 psi, and marks them as D3₁₀₀. The D3₅₀ and D3₁₀₀ parameters form the data density distribution, and are learned from every training example.

D3₅₀ of a training data is the fraction of total pressure points in that dataset which is matched to within 50 psi band. That is,

$$Abs [ {p}_{obs} - {p}_{sim} ] \leq 50 .$$

D3₁₀₀ of a training data is the fraction of total pressure points in that dataset which is matched to within 100 psi band. That is,

$$Abs [ {p}_{obs} - {p}_{sim} ] \leq 100 .$$

For all the pressure training set labeled as Good, the HMM model determines the values of D3₅₀ and D3₁₀₀, noting the minimum value of each parameter in the training dataset. For any well, for which history match quality is to be predicted, if its D3₅₀ and D3₁₀₀ values are respectively greater than the minimum of D3₅₀ and D3₁₀₀ obtained from the training dataset, then HMM labels the respective well as a Good quality pressure match. That is,

If D3₅₀well≥Min[D3₅₀GoodTrainingSet]AND D3₁₀₀well≥Min[D3₅₀GoodTrainingSet]

For all the pressure training set labeled as Acceptable, the HMM model determines the values of D3₅₀ and D3₁₀₀ considering the minimum value of each parameter in the training dataset. For any well for which quality is to be predicted, if its D3₅₀ and D3₁₀₀ values are respectively greater than the minimum D3₅₀ and D3₁₀₀ obtained from the training dataset, then HMM labels that well as an Acceptable quality pressure match. That is,

If D3₅₀well≥Min[D3₅₀AcceptableTrainingSet]AND D3₁₀₀well≥Min[D3₅₀AcceptableTrainingSet].

If a well satisfies both the Good and Acceptable criteria, the highest classification (Good) is retained. Any wells that do not fall within the Good or Acceptable classifications are automatically labeled as Poor.

For water-cut match, the corresponding quantities learned from the training dataset are, Good D3₀₅ and Acceptable D3₁₀.

D3₀₅ of a training data is the fraction of total water-cut points in that dataset which is matched to within 5% band. That is,

$$Abs [ {wcut}_{obs} - {wcut}_{sim} ] \leq 0.05$$

D3₁₀ of a training data is the fraction of total water-cut points in that dataset which is matched to within 10% band. That is,

$$Abs [ {wcut}_{obs} - {wcut}_{sim} ] \leq 0.1 .$$

An additional feature consideration is given to water-cut history matching training and assessment. The additional feature consideration relates to the history match quality of water-breakthrough time. Water breakthrough (BT) time is that time, when water first appears as part of a well's produced fluids, such produced water may be arriving from the reservoir's adjoining aquifer or from injected water. Water breakthrough is undesirable, though unavoidable in reservoirs undergoing water injection or having aquifer support. Adequate history match of water breakthrough time is an indication of proper representation of the mechanism and speed of water invasion of the oil pool, which has implications for future reservoir performance and development planning. An additional feature termed breakthrough mismatch (BT_{mismatch}) is determined from the water-cut training dataset. The BT_{mismatch} of a training data set is the difference in months between the date of historical water breakthrough and the date of simulated water breakthrough. That is,

$${BT}_{mismatch} = Abs [ {BT}_{obs} - {BT}_{sim} ] .$$

For all the water-cut training set labeled by the human as Good, the HMM model determines the values of D3₀₅, D3₁₀ and BT_{mismatch}, and takes note of the minimum values of the D3 parameters and the maximum value of BT_{mismatch} of the training dataset. For any well whose water-cut history match quality is to be predicted, if its D3₀₅ and D3₁₀ values are greater than the minimum obtained from the training dataset, AND its BT_{mismatch} is less than the maximum value of BT__{mismatch} from the dataset, then HMM labels that well as a Good quality water-cut match. That is,

If D3₀₅well≥Min[D3₀₅GoodTrainingSet]AND D3₁₀well≥Min[D3₁₀GoodTrainingSet]AND BT_{mismatch}^{well}≤Max[BT_{mismatch}GoodTrainingSet],then HMQA=Good.

At 204A, the HMM model separately determines, for each training data (well match) corresponding to a particular parameter match (e.g., the pressure match assessment being processed separately from the water cut match) within a data distribution. The parameters within a group correspond to the same data type (e.g., only water cuts, or only static bottomhole pressures). The parameters can then be grouped by well or by area, or they can represent the entire set of deviations for the data type itself. The HMM model also determines, for the pressure match assessment, what fraction of the total pressure points were matched to within 50 psi of the pressure data density distribution, referred to as D3₅₀ that correspond to a Good match. The HMM model also determines, what fraction of the total (pressure) points were matched to within 100 psi, D3₁₀₀ of the pressure data density distribution that correspond to an Acceptable match. D3₅₀ of a training data is the fraction of total pressure points in that data which is matched within 50 psi band. D3₁₀₀ of a training data is the fraction of total pressure points in that data which is matched within 100 psi band.

At 204B, the HMM model separately determines, a quality level of the water cut match using the training data and the respective water cut data distribution. The HMM model determines, for the water cut match assessment, the D3₀₅ of a training data, which is the fraction of total water-cut points in that data which is matched within 5 units band. The HMM model also determines D3₁₀ of a water cut training data, which is the fraction of total water-cut points in that data, which is matched within 10 units band. In particular, water-cut matching requires attention to the water-breakthrough feature. A well can produce for several months or years only single-phase oil. After a set period of time, due to either aquifer water influx or water injection, water arrives at the well and it begins to produce multi-phase oil and water. Matching the arrival of water at the well can be used for reservoir characterization. The arrival of water can be defined as a parameter feature breakthrough (BT)_mismatch. The BT_mismatch of a training data set is the difference in months between the date of historical water breakthrough and the date of simulated water breakthrough.

At 206A, for all the training set labeled as Good, the HMM model identifies the minimum value of D3₅₀ and the minimum value of D3₁₀₀. For any other well whose history-match quality is to be predicted, if the D3₅₀ value and D3₁₀₀ values are greater than that obtained from the training data, then it labels that well as a Good quality. For all the training set labeled as Acceptable, the HMM model can be trained to identify the minimum value of D3₅₀ and the minimum value of D3₁₀₀. For any other well whose quality is to be predicted, if the D3₅₀ and D3₁₀₀ values are greater than that obtained from the training data, then it labels that well as an Acceptable quality. Any wells that are determined as being excluded from the Good and Acceptable categories are automatically labeled as being included in the Poor category.

At 208, the labeled categories of match levels can be represented using annotations (e.g., differentiating highlights) that can be added to the respective data density distribution. The annotations can include a color codes indicative of different categories, such as yellow for Acceptable categories, green for Good categories, and red for Poor categories.

At 206B, for all the training set of water cut match assessment labeled as Good, the HMM model identifies the minimum value of D3₀₅, the minimum value of D3₁₀, and the maximum value of BT_mismatch. For any other well whose history-match quality is to be predicted, if the D3₀₅ and D3₁₀ values are greater than minimum obtained from the training data, and the BT_mismatch is less than the maximum obtained from the training data, then it labels that well as a Good quality. For all the training set of the water cut match assessment labeled as Acceptable, the HMM model takes note of the minimum value of D3₀₅, minimum value of D3₁₀ and the maximum value of BT_mismatch. For any other well whose quality is to be predicted, if the D3₀₅ and D3₁₀ value are greater than the minimum values obtained from the training data, and the BT_mismatch is less than the maximum obtained from the training dataset, then it labels that well as an Acceptable quality. Any water cut match assessment value that do not fall within the Good and Acceptable categories are automatically labeled as Poor. In some implementations, the analysis results derived for different parameters (pressure match assessment, water cut match assessment, and modular dynamic tester match assessment) are combined for planning operations related to a region including one or more reservoirs.

At 210, new wells are planned and prioritized in areas with Good D3₅₀, D3₀₅ and Acceptable D3₁₀₀, D3₁₀ matches, indicative of an Acceptable reservoir characterization of reservoir behavior derived for different parameters (pressure match assessment, water cut match assessment, and modular dynamic tester match assessment). Using the assessment of the wells' history match quality, the HMM model generates a spatial map of all the well locations and annotates (using color codes) each well location according to its HMQA result. The annotations can include green color for Good, orange color for Acceptable, and red color for Poor.

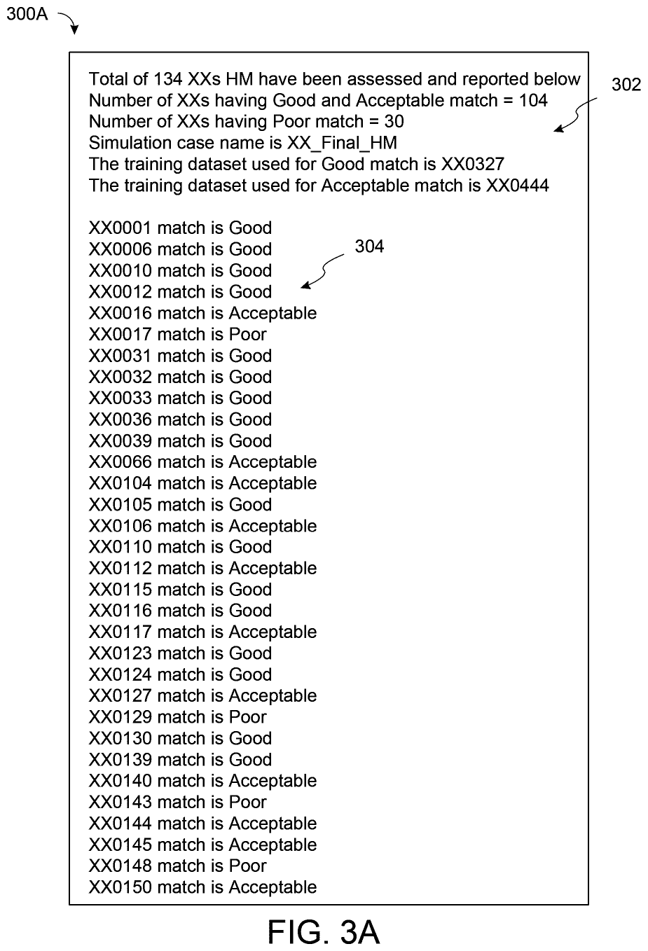

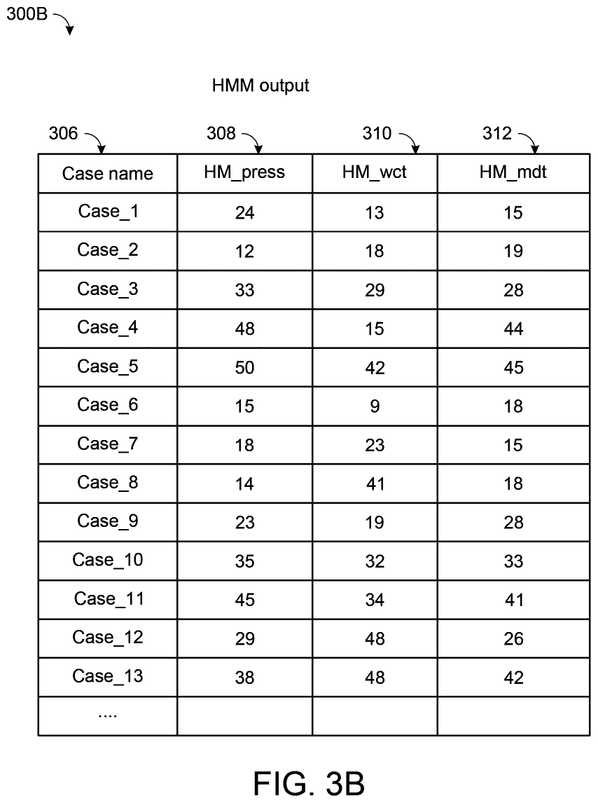

GoodGoodAcceptableAcceptableGoodAcceptablePoor FIG. 3A illustrates an example realization evaluation report 300A generated by the example system that can be used to execute implementations of the present disclosure. The example realization evaluation report 300A can be generated by an HMM model included in a trained model (e.g., the trained model 110 described with reference to FIG. 1). The example realization evaluation report 300A can be generated during the example workflow 200, illustrated in FIG. 2. The example realization evaluation report 300A can include a textual summary 302 of the example workflow 200 and a list of value characterization 304. The list of value characterization 304 includes the identified matching labels, such as Good, Acceptable, and Poor. The example realization evaluation report 300A can be stored as simulated data in memory of a system, as described with reference to FIG. 1.

FIG. 3B depicts an example multi-parameter comparison report 300B generated by the example system that can be used to execute implementations of the present disclosure. The example multi-parameter comparison report 300B can be generated by an HMM model included in a trained model (e.g., the trained model 110 described with reference to FIG. 1). The example multi-parameter comparison report 300B can be generated during the example workflow 200, illustrated in FIG. 2. The example multi-parameter comparison report 300B can be formatted as a table including multiple rows and columns. The columns 306, 308, 310, and 312 can correspond to different case names and parameters (e.g., pressure match assessment, water cut match assessment, and modular dynamic test match assessment). The rows of the example multi-parameter comparison report 300B can include corresponding values for each case. The number in each column represents the number of wells in which the history-match quality has been assessed as Good or Acceptable for each of the simulation cases. The example multi-parameter comparison report 300B can be stored as simulated data in memory of a system, as described with reference to FIG. 1.

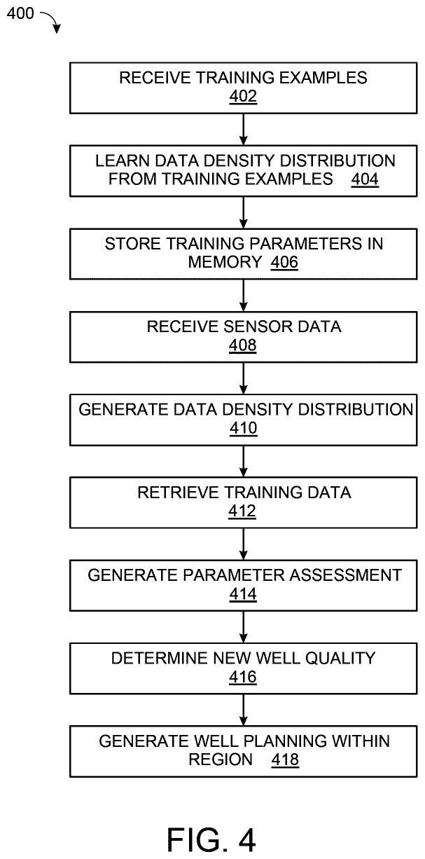

FIG. 4 depicts a flowchart illustrating an example process 400 for artificial intelligence (e.g., machine learning) driven history-match quality assessment, in accordance with some example implementations. Referring to FIG. 1, the process 400 can be performed by any components of the example system 100. The example process 400 can be executed using, e.g., any component of the example system 100 described with reference to FIG. 1. Operations of the process 400 are described below for illustration purposes only. Operations of the process 400 can be performed by any appropriate device or system, e.g., any appropriate data processing apparatus. Operations of the process 400 can also be implemented as instructions stored on a computer readable medium which can be non-transitory. Execution of the instructions causes one or more data processing apparatus to perform operations of the process 400.

At 402, training examples for training a prediction model are received. The training examples include at least one example of history-match labeled as a Good match and at least one example labeled as an Acceptable match between historically simulated and physically measured well data (e.g., D3₅₀, D3₀₅ Good matches and Acceptable D3₁₀₀, D3₁₀ matches discussed with reference to FIG. 2). Historically simulated well data includes data generated by a three-dimensional simulation model of a well located in a proximity of a hydrocarbon reservoir. The historically simulated well data includes (pressure, water cut, and modular dynamic test) data that varies over time relative to one or more well operations. Historically physically measured well data includes data generated by sensors within or near a respective well located in a proximity of the hydrocarbon reservoir, at multiple points in time (e.g., before, during, and after well operations). In some implementations, the history-matching labels are generated in response to receiving a user input identifying a match type. In some implementations, more than one match type can be received for training a prediction model.

At 404, data density distribution is used for training a prediction model including an artificial intelligence (e.g., machine learning, such as HMM) examples configured for history-match classification. In one or more implementations, labeled relationships between the physically measured well data and the simulated data can be used for training the prediction model. During training of the prediction model, the datasets are processed for the prediction model to learn the data density distribution, and to retrieve the parameters to be used for quality assessment of other wells. The training step optimizes the weights and biases in the hidden and output layer of the prediction model, such that the estimation error between the estimated (Good, Acceptable, or Poor) classification and the labeled classification of the training examples can be minimized. The classification estimation can be optimized using multiple training datasets or batches (e.g., corresponding to multiple reservoirs) with training samples randomly selected at a time. The optimization process can optimize the weights and biases associated with the vertical and horizontal semi-variances, and other input features such that an error in the classification estimation relative to the received labels can be minimized. The process of training described here not only can minimize the error in history-match classification. Following the completion of training, the accuracy of the prediction model can be determined by using a validation dataset, for which the output of the prediction model can be approved by a user input. The training dataset is validated by comparing predictions of the HMM with a second set of labeled examples that were excluded from training. For example, cross-validation techniques can be used to split the labeled data into training and validation sets. In some implementations, statistical tests can be performed to validate the model's predictions. The validation can include testing to determine if the HMM outputs significantly differ from expected results. In response to determining that the training is complete, the validated D3 properties of the input labelled examples are applied by the HMM model to predict the labels of the input data using the training examples.

At 406, the training parameters are stored in memory (e.g., memory 114 described with reference to FIG. 1), making them accessible to the prediction models for being used on other data sets including probe data.

At 408, the probe data is received, by the one or more processors of a server system configured to process the probe data. The probe data can be collected by probes included within a region that can include one or more hydrocarbon reservoirs, such as in or near operating wells and observation wells within a field. The probe data can include surface data collected by probes located on or near a wellhead and subterranean data located within or near a downhole, the probe data being indicative of a health of a gas storage reservoir within the field. For example, the probe data can include field injection rate, injected volume, well performance parameters, pressure measurements at different locations, temperatures at multiple locations, seismic (microseismic) data, bottomhole pressure, fluid composition, flow rate, reproduction rate, and any other measurable variable parameter indicative of a well operation and/or efficiency. The probes can include pressure sensors (e.g., dynamic pressure sensors, including pressure controllers), phase dynamic water cut sensors (e.g., designed to measure the water content in oil and providing accurate and real-time data for various applications in the oil and gas industry) and modular dynamic test systems (e.g., compact, robust, and highly accurate electronic pressure sensors that offer a solution for optimizing process measurement performance). Each of the probes can be configured to activate data collection and/or transmission according to a respective schedule defining a frequency of data collection and a duration of each collection duration. The probes can be configured to collect data continuously (e.g., according to the respective schedule) or can have a set trigger that initiates data collection in response to detection of one or more conditions for data collection.

At 410, simulated data (simulation results) corresponding to the probe data can be retrieved by one or more processors (e.g., processor 118A described with reference to FIG. 1) from a database (e.g., the memory 114 described with reference to FIG. 1) to generate a data density distribution as a correlation function, such as a graphical representation (e.g., a two-dimensional map). The data density distribution shows whether a simulator is over or under-predicting surveillance data of a particular type, and the general degree of that match. The data density distribution can include aligned values and deviations that can be converted to a relative measure of the confidence that the simulation model reproduced a particular reservoir performance at the time the surveillance measurement was made. In some implementations, the simulated data include simulation results generated using different simulation parameters for identical data inputs. The large volume of data involved in history matching simulators is stored by large surveillance databases, such that a simulator-specific computer program can be used to extract the simulated data from the simulator's output file.

At 412, training datasets of reservoir performance corresponding to the probe data can be retrieved by one or more processors (e.g., processor 118A described with reference to FIG. 1) from a database (e.g., memory 114 described with reference to FIG. 1). The data density distribution can be characterized by using the training datasets of corresponding parameters. The training data sets can include labeled parameter distributions including labels identifying matches between recorded (surveillance) data and simulated (simulation predicted) parameters. The labels (Acceptable, Good, and Poor) can be added to the training data sets as separate values included directly in the tables of the training datasets or as metadata associated with the training data sets.

At 414, the data density distribution is matched to the training data to generate a parameter match assessment (e.g., pressure match assessment and a water cut assessment). Matching the data density distribution to the training data can include determining a fraction (e.g., percentage) of matching data-points to generate a parameter match assessment, as described with reference to FIG. 2. The parameter match assessment can include adding labels characterizing identified match quality levels. The parameter match assessment (e.g., pressure match assessment and a water cut assessment) can be executed using an HMM model, as described with reference to FIG. 2. The HMM can include trainable machine learning models, as described with reference to FIG. 1. The machine learning model can include a machine learning model pre-trained and fine-tuned to identify matching reservoir characterization. In some implementations, the machine learning model can be based on machine learning techniques related to a deep neural network (DNN). A deep neural network can be referred to as a network because it can be represented by connecting different functions. For example, a model of the DNN can be represented as a graph representing how the functions are connected from an input layer, through one or more hidden layers, and finally to an output layer, and each layer can have one or more nodes. In an example, the DNN of the subject technology generates a dynamic characterization of the data density distribution using the training data sets as templates, with low computational requirements. The DNN model can provide quantitative value for the match between of the recorded and simulated parameter distributions using the labeled parameter distributions. In one or more implementations, relationships between the received geologic data and simulated data can be determined during training of the DNN. The training step optimizes the weights and biases in the hidden and output layer such that the estimation error between the estimated property values and observed property values from the well log(s) can be minimized. Estimation error can be root mean square deviation, or a composite of root mean square deviation, cross-correlation, or a geoscience error metric. To avoid overfitting during training, regularization of the estimation error is performed based upon the norms of weights in the hidden layers that are added to the estimation error. An optimization process can include application of a stochastic gradient descent algorithm (or any other appropriate optimization algorithm), which can use one or more iterative optimization techniques and/or use a small subset of the training dataset or batch with training samples randomly selected at a time. The variances calculated based upon the horizontal and vertical semi-variograms are included in the input feature. The optimization process can optimize the weights and biases associated with the vertical and horizontal semi-variances, and other input features such that an error in the property estimates relative to the observed property values can be minimized. The process of training described here not only can minimize the error in characterization estimates, but also can incorporate spatial variance of the parameter distribution. Following the completion of training that can be determined by the estimation error on the validation dataset falling below a cut-off value, the testing dataset can be used to determine the performance of the trained DNN on unseen data records that were not previously used for training. Although a DNN was discussed for the purposes of explanation, it is appreciated that the machine learning model can include other trainable machine learning techniques. Further, it is appreciated that other types of neural networks can be utilized by the subject technology. For example, a convolutional neural network, regulatory feedback network, radial basis function network, recurrent neural network, modular neural network, instantaneously trained neural network, spiking neural network, regulatory feedback network, dynamic neural network, neuro-fuzzy network, compositional pattern-producing network, memory network, and/or any other appropriate type of neural network can be utilized.

At 416, a well quality within the field using the match assessment characterization for multiple parameters (e.g., pressure match assessment and the water cut assessment) can be integrated to provide an overall characterization of the respective well. The overall characterization of the respective well can include a quantitative score of well production. The value of the well score can depend on the data-types (e.g., pressure and/or water cut) used for the analysis. For example, the calculated score for an equivalent history match quality can be different if the data being assessed is derived separately from a water-cut (WCT) and a pressure match. If multiple data types are used, the overall scores for each well can be obtained by averaging the scores of each data type.

At 418, an action plan is generated, by the one or more processors of the server system, to optimize well operations and reservoir management. The determined quantitative score of well production can be compared to a reference score of the respective well type. The reference scores can be obtained from a database that stores the reference scores associated with a particular well or set of wells within a region of interest of a field. The reference scores represent a production potential of the well. The action plan can be identified by machine learning models (e.g., recurrent neural networks with a multi-layer network topology) trained and fine-tuned to generate a set of remedial actions to correct safety gaps. The system can determine scores for each system component to be validated based on a difference between each predicted value and the target production level for the respective field component, and the accuracy for the machine learning model that generated the predicted value. The trained machine learning models can be configured to operate in active mode, within the server system, facilitating automatic action plan implementation. For example, the trained machine learning models can trigger a modification of system component operations for adjusting pressure, temperature, and/or volume, for example by valve and/or pump control. In some implementations, before any of the operation adjustments are triggered (e.g., by activating the operation safety control system 134 described in FIG. 1), the respective potential benefits are first evaluated using a simulation model. The reliability of the results from a model depends on the reliability of the model. Areas where history match quality assessment indicate Good and Acceptable wells constitute reliable areas of the model, where the operation adjustments can be evaluated and subsequently implemented in the field. The operation adjustments can include automatic activation of flow rate adjustment (e.g., to automatically adjust the flow rate based on pressure and water cut data to maintain optimal production levels), pump control (e.g., to activate or deactivate pumps to manage fluid levels and prevent overproduction or underproduction), chemical injection systems (e.g., to automatically inject chemicals to manage scale, corrosion, or hydrate formation based on real-time well conditions), valve operation (e.g., to open or close valves to control the flow of fluids, ensuring balanced pressure and preventing blowouts), alarm systems (e.g., to trigger alarms for abnormal conditions such as sudden pressure drops or high water cut, enabling quick response to potential issues), data logging and reporting (e.g., to automatically log data and generate reports for analysis and regulatory compliance), maintenance scheduling (e.g., to schedule maintenance activities based on predictive analytics, reducing downtime and extending equipment life), artificial lift optimization (e.g., to adjust artificial lift systems like electric submersible pumps or gas lift systems to optimize production based on well performance data), well shut-in systems (e.g., to automatically shut in a well if critical parameters exceed safe operating limits, ensuring safety and preventing damage), and/or reservoir management systems (e.g., to adjust injection rates in waterflood or gas injection operations to optimize reservoir pressure and enhance recovery).

In some implementations, more than one trained machine model can be placed in active mode concurrently (that is, overlapping in a time), for example, for evaluating well operation safety considering different evaluation methods (e.g., one analyzing pressure, another analyzing temperature, another analyzing injected volume relative to a detected parameter, such as seismic data magnitude). The action plan is transmitted to be displayed by a graphical user interface. The action plan can include an automatic selection of industrial machine actions that can be triggered to be automatically execute well operations.

The example process 400 allows multi parameter match assessment characterization of wells and hydrocarbon reservoirs within a field. The example process 400 can be scheduled and automated, being initiated with probe data collection. The example process 400 provides accurate and consistent assessment results, by applying labels corresponding to set characterization standards. The data generated during the example process 400 is displayed on a user-friendly interface including various dashboards and reports, enabling a comprehensive performance analysis at field and well levels. The data generated during the example process 400 can automatically integrate surface and subsurface data, including microseismic data, to automatically update geomechanical models and issue recommendations for well and reservoir management.

FIG. 5 depicts a block diagram illustrating a computing system 500, in accordance with some example implementations. Referring to FIG. 1, the computing system 500 can be used to implement the computing device 102 and/or any other components of the example system 100.

As shown in FIG. 5, the computing system 500 can include a processor 510, a memory 520, a storage device 530, and input/output devices 540. The processor 510, the memory 520, the storage device 530, and the input/output devices 540 can be interconnected using a system bus 550. The processor 510 is capable of processing instructions for execution within the computing system 500. Such executed instructions can implement one or more components of, for example, the example system 100. In some implementations of the current subject matter, the processor 510 can be a single-threaded processor. Alternately, the processor 510 can be a multi-threaded processor. The processor 510 is capable of processing instructions stored in the memory 520 and/or on the storage device 530 to display graphical information for a user interface provided using the input/output device 540.

The memory 520 is a computer readable medium such as volatile or non-volatile that stores information within the computing system 500. The memory 520 can store data structures representing configuration object databases, for example. The storage device 530 is capable of providing persistent storage for the computing system 500. The storage device 530 can be a floppy disk device, a hard disk device, an optical disk device, or a tape device, or other suitable persistent storage means. The input/output device 540 provides input/output operations for the computing system 500. In some implementations of the current subject matter, the input/output device 540 includes a keyboard and/or pointing device. In various implementations, the input/output device 540 includes a display unit for displaying graphical user interfaces.

According to some implementations of the current subject matter, the input/output device 540 can provide input/output operations for a network device. For example, the input/output device 540 can include Ethernet ports or other networking ports to communicate with one or more wired and/or wireless networks (e.g., a local area network (LAN), a wide area network (WAN), the Internet).

In some implementations of the current subject matter, the computing system 500 can be used to execute various interactive computer software applications that can be used for organization, analysis and/or storage of data in various (e.g., tabular) format (e.g., Microsoft Excel®, and/or any other type of software). Alternatively, the computing system 500 can be used to execute any type of software applications. These applications can be used to perform various functionalities, e.g., planning functionalities (e.g., generating, managing, editing of spreadsheet documents, word processing documents, and/or any other objects), computing functionalities, or communications functionalities. The applications can include various add-in functionalities or can be standalone computing products and/or functionalities. Upon activation within the applications, the functionalities can be used to generate the user interface provided using the input/output device 540. The user interface can be generated and presented to a user by the computing system 500 (e.g., on a computer screen monitor).

One or more aspects or features of the subject matter described herein can be realized in digital electronic circuitry, integrated circuitry, specially designed ASICs, field programmable gate arrays (FPGAs) computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system can include clients and servers. A client and server are generally remote from each other and typically interact through a communication network. The relationship of client and server arises by virtue of computer programs running on the respective computers and having a client-server relationship to each other.

These computer programs, which can also be referred to as programs, software, software applications, applications, components, or code, include machine instructions for a programmable processor, and can be implemented in a high-level procedural and/or object-oriented programming language, and/or in assembly/machine language. As used herein, the term “machine-readable medium” refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” refers to any signal used to provide machine instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example, as would a processor cache or other random-access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user can provide input to the computer. Other kinds of devices can be used to provide for interaction with a user as well. For example, feedback provided to the user can be any form of sensory feedback, such as for example visual feedback, auditory feedback, or tactile feedback; and input from the user can be received in any form, including acoustic, speech, or tactile input. Other possible input devices include touch screens or other touch-sensitive devices such as single or multi-point resistive or capacitive track pads, voice recognition hardware and software, optical scanners, optical pointers, digital image capture devices and associated interpretation software, and the like.

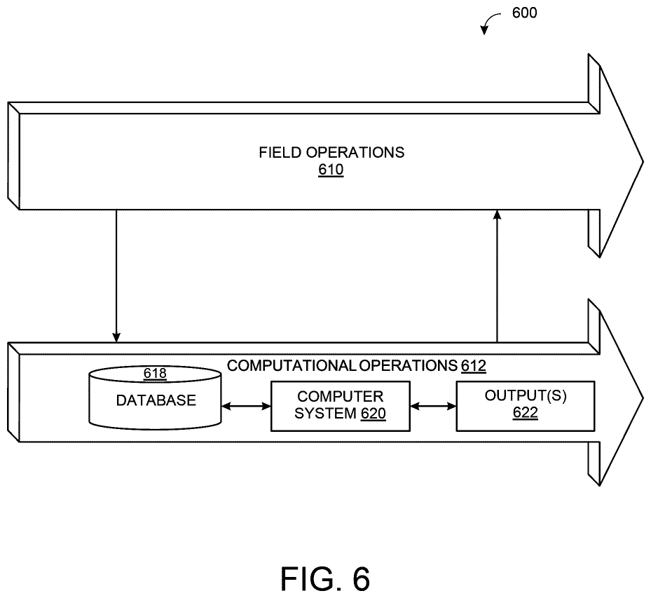

FIG. 6 illustrates hydrocarbon production operations 600 that include both one or more field operations 610 and one or more computational operations 612, which exchange information and control exploration for the production of hydrocarbons. In some implementations, outputs of techniques of the present disclosure can be performed before, during, or in combination with the hydrocarbon production operations 600, specifically, for example, either as field operations 610 or computational operations 612, or both.

Examples of field operations 610 include forming/drilling a wellbore, hydraulic fracturing, producing through the wellbore, injecting fluids (such as water) through the wellbore, to name a few. In some implementations, methods of the present disclosure can trigger or control the field operations 610. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 610 and responsively triggering the field operations 610 including, for example, generating plans and signals that provide feedback to and control physical components of the field operations 610. Alternatively, or in addition, the field operations 610 can trigger the methods of the present disclosure. For example, implementing physical components (including, for example, hardware, such as sensors) deployed in the field operations 610 can generate plans and signals that can be provided as input or feedback (or both) to the methods of the present disclosure.

Examples of computational operations 612 include one or more computer systems 620 that include one or more processors and computer-readable media (e.g., non-transitory computer-readable media) operatively coupled to the one or more processors to execute computer operations to perform the methods of the present disclosure. The computational operations 612 can be implemented using one or more databases 618, which store data received from the field operations 610 and/or generated internally within the computational operations 612 (e.g., by implementing the methods of the present disclosure) or both. For example, the one or more computer systems 620 process inputs from the field operations 610 to assess conditions in the physical world, the outputs of which are stored in the databases 618. For example, seismic sensors of the field operations 610 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 612 where they are stored in the databases 618 and analyzed by the one or more computer systems 620.

In some implementations, one or more outputs 622 generated by the one or more computer systems 620 can be provided as feedback/input to the field operations 610 (either as direct input or stored in the databases 618). The field operations 610 can use the feedback/input to control physical components used to perform the field operations 610 in the real world.

For example, the computational operations 612 can process the seismic data to generate three-dimensional (3D) maps of the subsurface formation. The computational operations 612 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 612 to process new information about the formation and control the drilling to adjust to the observed conditions in real-time.

The one or more computer systems 620 can update the 3D maps of the subsurface formation as information from one exploration well is received and the computational operations 612 can adjust the location of the next exploration well based on the updated 3D maps. Similarly, the data received from production operations can be used by the computational operations 612 to control components of the production operations. For example, production well and pipeline data can be analyzed to predict slugging in pipelines leading to a refinery and the computational operations 612 can control machine operated valves upstream of the refinery to reduce the likelihood of plant disruptions that run the risk of taking the plant offline.

In some implementations of the computational operations 612, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 6 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart or are located in different countries or other jurisdictions.

The preceding figures and accompanying description illustrate example processes and computer implementable techniques. The environments and systems described above (or their software or other components) can contemplate using, implementing, or executing any suitable technique for performing these and other tasks. It will be understood that these processes are for illustration purposes only and that the described or similar techniques can be performed at any appropriate time, including concurrently, individually, in parallel, and/or in combination. In addition, many of the operations in these processes can take place simultaneously, concurrently, in parallel, and/or in different orders than as shown. Moreover, processes can have additional operations, fewer operations, and/or different operations, so long as the methods remain appropriate.

In other words, although the disclosure has been described in terms of certain implementations and generally associated methods, alterations and permutations of these implementations, and methods will be apparent to those skilled in the art. Accordingly, the above description of example implementations does not define or constrain the disclosure. Other changes, substitutions, and alterations are also possible without departing from the spirit and scope of the disclosure.

A number of implementations of the present disclosure have been described. Nevertheless, it will be understood that various modifications can be made without departing from the spirit and scope of the present disclosure. Accordingly, other implementations are within the scope of the following claims.

In view of the above-described implementations of subject matter this application discloses the following list of examples, wherein one feature of an example in isolation or more than one feature of said example taken in combination and, optionally, in combination with one or more features of one or more further examples are further examples also falling within the disclosure of this application.

Example 1. A computer-implemented method comprising: receiving, by one or more processors from probes, wherein the probe data is collected by probes included in operating wells or observation wells within a field, and wherein the probe data comprises parameters characterizing a surface field conditions and subterranean field conditions indicative of a health of a reservoir within the field; receiving, by the one or more processors, as input a list of training dataset comprising of examples of simulated data versus the probe data labelled as Good matches and Acceptable matches; learning, by the one or more processors, a data density distribution comprising a matching between the probe data and simulated data for respective parameters; retrieving, by the one or more processors, training parameters for subsequent history-match assessment from the labeled input for the respective parameters; determining, by the one or more processors, a well history-match quality within the field using the parameter match assessment; providing, by the one or more processors, well planning within the field based on the well history-match quality map, the well planning comprising a plurality of operations affecting the drilling of sidetrack or infill wells within the field; and triggering, by the one or more processors, execution of one of the plurality of operations.

Example 2. The computer-implemented method of the preceding example, comprising: displaying an interactive spreadsheet on a display of a user device, wherein the interactive spreadsheet comprises parameter matches; receiving an input differentiating between Acceptable data, Good, and Poor data; in response to receiving the input: training a machine learning model on recorded to simulated parameter matches to predict Acceptable data and Good data; generating a respective predicted value for a parameter distribution; and displaying the respective predicted value on the user device.

Example 3. The computer-implemented method of any of the preceding examples, wherein training the machine learning model occurs on the user device.

Example 4. The computer-implemented method of any of the preceding examples, wherein the probe data comprises pressures, water-cut and modular dynamic test data.

Example 5. The computer-implemented method of any of the preceding examples, wherein determining, by the one or more processors, the well quality within the field is performed without receiving any additional user inputs.

Example 6. The computer-implemented method of any of the preceding examples, wherein matching, by the one or more processors, the data density distribution to the training data comprises determining a fraction of matching data-points.

Example 7. The computer-implemented method of any of the preceding examples, wherein matching, by the one or more processors, the probe data comprises determining a data density distribution.

Example 8. A computer-implemented system comprising: one or more computers; and one or more computer memory devices interoperably coupled with the one or more computers and having tangible, non-transitory, machine-readable media storing one or more instructions that, when executed by the one or more computers, perform one or more operations comprising: receiving, from probes, wherein the probe data is collected by probes included in operating wells or observation wells within a field, and wherein the probe data comprises parameters characterizing a surface field conditions and subterranean field conditions indicative of a health of a reservoir within the field; receiving as input a list of training dataset comprising of examples of simulated data versus the probe data labelled as Good matches and Acceptable matches; learning a data density distribution comprising a matching between the probe data and simulated data for respective parameters; retrieving training parameters for subsequent history-match assessment from the labeled input for the respective parameters; determining a well history-match quality within the field using the parameter match assessment; providing well planning within the field based on the well history-match quality map, the well planning comprising a plurality of operations affecting the drilling of sidetrack or infill wells within the field; and triggering execution of one of the plurality of operations.

Example 9. The computer-implemented system of the preceding example, wherein the operations further comprise: displaying an interactive spreadsheet on a display of a user device, wherein the interactive spreadsheet comprises parameter matches; receiving an input differentiating between Acceptable data, Good, and Poor data; in response to receiving the input: training a machine learning model on recorded to simulated parameter matches to predict Acceptable data and Good data; generating a respective predicted value for a parameter distribution; and displaying the respective predicted value on the user device.

Example 10. The computer-implemented system of any of the preceding examples, wherein training the machine learning model occurs on the user device.

Example 11. The computer-implemented system of any of the preceding examples, wherein the probe data comprises pressures, water-cut and modular dynamic test data.

Example 12. The computer-implemented system of any of the preceding examples, wherein determining the well quality within the field is performed without receiving any additional user inputs.

Example 13. The computer-implemented system of any of the preceding examples, wherein matching the data density distribution to the training data comprises determining a fraction of matching data-points.

Example 14. The computer-implemented system of any of the preceding examples, wherein matching the probe data comprises determining a data density distribution.

Example 15. A non-transitory computer-readable media encoded with a computer program, the computer program comprising instructions that when executed by one or more computers cause the one or more computers to perform operations comprising: receiving, from probes, wherein the probe data is collected by probes included in operating wells or observation wells within a field, and wherein the probe data comprises parameters characterizing a surface field conditions and subterranean field conditions indicative of a health of a reservoir within the field; receiving as input a list of training dataset comprising of examples of simulated data versus the probe data labelled as Good matches and Acceptable matches; learning a data density distribution comprising a matching between the probe data and simulated data for respective parameters; retrieving training parameters for subsequent history-match assessment from the labeled input for the respective parameters; determining a well history-match quality within the field using the parameter match assessment; providing well planning within the field based on the well history-match quality map, the well planning comprising a plurality of operations affecting the drilling of sidetrack or infill wells within the field; and triggering execution of one of the plurality of operations.

Example 16. The non-transitory computer-readable media of the preceding example, wherein the operations further comprise: displaying an interactive spreadsheet on a display of a user device, wherein the interactive spreadsheet comprises parameter matches; receiving an input differentiating between Acceptable data, Good, and Poor data; in response to receiving the input: training a machine learning model on recorded to simulated parameter matches to predict Acceptable data and Good data; generating a respective predicted value for a parameter distribution; and displaying the respective predicted value on the user device, wherein training the machine learning model occurs on the user device.

Example 17. The non-transitory computer-readable media of any of the preceding examples, wherein the probe data comprises pressures, water-cut and modular dynamic test data.

Example 18. The non-transitory computer-readable media of any of the preceding examples, wherein determining the well quality within the field is performed without receiving any additional user inputs.

Example 19. The non-transitory computer-readable media of any of the preceding examples, wherein matching the data density distribution to the training data comprises determining a fraction of matching data-points.

Example 20. The non-transitory computer-readable media of any of the preceding examples, wherein matching the probe data comprises determining a data density distribution.

What is claimed is:

1. A computer-implemented method comprising:
receiving, by one or more processors, probe data, wherein the probe data is collected by probes included in operating wells or observation wells within a field, and wherein the probe data comprises parameters characterizing a surface field conditions and subterranean field conditions indicative of a health of a reservoir within the field;
receiving, by the one or more processors and, as labeled input, a list of training datasets comprising examples of simulated data versus the probe data and labeled as Good matches and Acceptable matches;
learning, by the one or more processors, a data density distribution comprising a matching between the probe data and simulated data for respective parameters;
retrieving, by the one or more processors, training parameters for subsequent history-match assessment from the labeled input for the respective parameters;
determining, by the one or more processors, a well history-match quality map within the field using the parameter match assessment;
providing, by the one or more processors, well planning within the field based on the well history-match quality map, the well planning comprising a plurality of field operations affecting drilling of sidetrack or infill wells within the field; and
triggering, by the one or more processors, execution of one of the plurality of operations.

2. The computer-implemented method of claim 1, comprising:
displaying an interactive spreadsheet on a display of a user device, wherein the interactive spreadsheet comprises parameter matches;
receiving an input differentiating between Acceptable data, Good, and Poor data;
in response to receiving the input:
training a machine learning model on recorded to simulated parameter matches to predict Acceptable data and Good data;
generating a respective predicted value for a parameter distribution; and
displaying the respective predicted value on the user device.

3. The computer-implemented method of claim 2, wherein training the machine learning model occurs on the user device.

4. The computer-implemented method of claim 1, wherein the probe data comprises pressures, water-cut and modular dynamic test data.

5. The computer-implemented method of claim 1, wherein determining, by the one or more processors, the well history-match quality map within the field is performed without receiving any additional user inputs.

6. The computer-implemented method of claim 1, wherein determining, by the one or more processors, the well history-match quality map comprises determining a fraction of matching data-points.

7. The computer-implemented method of claim 1, wherein determining, by the one or more processors, the well history-match quality map comprises determining a data density distribution.

8. A computer-implemented system comprising:
one or more computers; and
one or more computer memory devices interoperably coupled with the one or more computers and having tangible, non-transitory, machine-readable media storing one or more instructions that, when executed by the one or more computers, perform operations comprising:
receiving probe data, wherein the probe data is collected by probes included in operating wells or observation wells within a field, and wherein the probe data comprises parameters characterizing a surface field conditions and subterranean field conditions indicative of a health of a reservoir within the field;
receiving, as labeled input, a list of training datasets comprising examples of simulated data versus the probe data and labeled as Good matches and Acceptable matches;
learning a data density distribution comprising a matching between the probe data and simulated data for respective parameters;
retrieving training parameters for subsequent history-match assessment from the labeled input for the respective parameters;
determining a well history-match quality map within the field using the parameter match assessment;
providing well planning within the field based on the well history-match quality map, the well planning comprising a plurality of field operations affecting drilling of sidetrack or infill wells within the field; and
triggering execution of one of the plurality of operations.

9. The computer-implemented system of claim 8, wherein the operations further comprise:
displaying an interactive spreadsheet on a display of a user device, wherein the interactive spreadsheet comprises parameter matches;
receiving an input differentiating between Acceptable data, Good, and Poor data;
in response to receiving the input:
training a machine learning model on recorded to simulated parameter matches to predict Acceptable data and Good data;
generating a respective predicted value for a parameter distribution; and
displaying the respective predicted value on the user device.

10. The computer-implemented system of claim 9, wherein training the machine learning model occurs on the user device.

11. The computer-implemented system of claim 8, wherein the probe data comprises pressures, water-cut and modular dynamic test data.

12. The computer-implemented system of claim 8, wherein determining the well history-match quality map within the field is performed without receiving any additional user inputs.

13. The computer-implemented system of claim 8, wherein determining the well history-match quality map comprises determining a fraction of matching data-points.

14. The computer-implemented system of claim 8, wherein determining the well history-match quality map comprises determining a data density distribution.

15. A non-transitory computer-readable media encoded with a computer program, the computer program comprising instructions that when executed by one or more computers cause the one or more computers to perform operations comprising:
receiving probe data, wherein the probe data is collected by probes included in operating wells or observation wells within a field, and wherein the probe data comprises parameters characterizing a surface field conditions and subterranean field conditions indicative of a health of a reservoir within the field;
receiving, as labeled input, a list of training datasets comprising examples of simulated data versus the probe data and labeled as Good matches and Acceptable matches;
learning a data density distribution comprising a matching between the probe data and simulated data for respective parameters;
retrieving training parameters for subsequent history-match assessment from the labeled input for the respective parameters;
determining a well history-match quality map within the field using the parameter match assessment;
providing well planning within the field based on the well history-match quality map, the well planning comprising a plurality of field operations affecting drilling of sidetrack or infill wells within the field; and
triggering execution of one of the plurality of operations.

16. The non-transitory computer-readable media of claim 15, wherein the operations further comprise:
displaying an interactive spreadsheet on a display of a user device, wherein the interactive spreadsheet comprises parameter matches;
receiving an input differentiating between Acceptable data, Good, and Poor data;
in response to receiving the input:
training a machine learning model on recorded to simulated parameter matches to predict Acceptable data and Good data;
generating a respective predicted value for a parameter distribution; and
displaying the respective predicted value on the user device, wherein training the machine learning model occurs on the user device.

17. The non-transitory computer-readable media of claim 15, wherein the probe data comprises pressures, water-cut and modular dynamic test data.

18. The non-transitory computer-readable media of claim 15, wherein determining the well history-match quality map within the field is performed without receiving any additional user inputs.

19. The non-transitory computer-readable media of claim 15, wherein determining the well history-match quality map comprises determining a fraction of matching data-points.

20. The non-transitory computer-readable media of claim 15, wherein determining the well history-match quality map comprises determining a data density distribution.
